(19) United States
(12) Patent Application Publication
(10) Pub. No.: US 2024/0363476 A1
(43) Pub. Date: Oct. 31, 2024

(54) HYBRID DIAMOND BASED HEAT SPREADERS

(71) Applicant: Phononics Ltd, Nesher (IL)

(72) Inventors: Shye Shapira, Kiryat Tivon (IL); Inbar Dag, Nesher (IL); Anna Kosinova, Nesher (IL); Shaul Michaelson, Nesher (IL)

(73) Assignee: Phononics Ltd, Nesher (IL)

(21) Appl. No.: 18/309,827

(22) Filed: Apr. 30, 2023

(51) Int. Cl. H01L 23/373; H01L 21/48

(52) U.S. Cl. CPC H01L 23/3732; H01L 21/4803

(57) ABSTRACT

A semiconductor unit that includes a hot areas generating portion that generates hot areas during operation; and hybrid diamond heat spreaders (HDHSs) that are configured to dissipate at least part of the heat generated in the hot areas. A HDHS includes a diamond layer of a first thickness, a first mechanical strength, a first thermal conductivity, and a first coefficient of thermal expansion (CTE) and a diamond layer support element of a second thickness, a second mechanical strength, and a second CTE. According to one or more embodiments at least one of the following is true: (a) the first thickness is lower than the second thickness, (b) the first mechanical strength is higher than the second mechanical strength, (c) the first thermal conductivity exceeds the second thermal conductivity and (d) the second CTE exceeds the first CTE.

### BACKGROUND

A modern integrated circuit (IC) chip 11 has modes of operation where certain areas, “hot areas” 12, generate a high heat flux (high heat power flow per unit area) where others do not (FIG. 1). The dimensions of these hot operation areas may be from 1 mm² to 50 mm², where the chip may be 1 mm² to 2500 mm². The chip thickness in a package may be from 5 to 1500 microns. In multicore processors the processor cores are “hot operation areas”.

For clarity we describe in some detail the “hot operation area” problem in ICs implemented in silicon chips where the performance limited is the speed of the IC. “Hot operation areas” or “hot areas” limiting the performance and the reliability of electronic systems are common to all semiconductor chip-based systems, also ones that contain discrete devices such as power management and microwave power devices, implemented in silicon or other semiconductors such as GaN or SiC. The performance limited in such systems may be the maximum output power of the device or some other figure of merit. The dimensions of the hot areas may be smaller. This invention pertains to all such systems.

The proper operation and reliability of the IC is limited by the operating temperature in the chip. In silicon-based ICs it should normally not exceed 100 degrees centigrade. Thus, the speed of the IC operation (“clock speed”) is limited by the maximum operating temperature at the hot areas and its variation between them. Chip cooling methods, such as heat pipes, heat sinks, and active cooling systems have an upper limit for the heat flux they can remove from chip, while keeping the junction temperature below the maximum allowed operating temperature.

Thus, when a cooling system is used to cool a chip that has hot areas, its performance is limited by these hot areas. In the lower heat flux regions, the full capacity of the cooling system is not utilized. In such conditions the chip operation speed does not obtain its maximum possible level as enabled by the cooling method.

Diamond heat spreaders may be used to dissipate heat generated in the hot areas.

A major challenge in the diamond heat spreader integration in electronic device is the price per unit area of a diamond layer, which is high. On the other hand, a diamond layer spreads most of the heat laterally onto and area larger by the dimensions of it thickness. Thus, the portion of the diamond under the “hot operation areas” that contributes the most to the heat spreading is of dimensions the hot operation area and the diamond thickness.

Another major challenge in using a diamond heat spreader is its low coefficient thermal expansion, CTE, around 1 ppm/deg C. When bonded to another material, hosting a device, the temperature changes and the higher CTE of the device hosting material will cause mechanical stress which may impact the device performance and reliability through various mechanical effects, stress. cracks etc.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that can be executed by the system.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings:

FIG. 1 is an example of hot areas on an active silicon chip;

FIGS. 2A, 2B and 2C are examples of cross sectional view of a silicon chip in package;

FIG. 3 is an example of an impact for high thermal conductivity heat spreader such as a microcrystalline diamond heat spreader on hot area temperature;

FIG. 4 illustrates various examples of heterogeneous heat spreaders with embedded high thermal conductivity material;

FIGS. 5A-5B illustrate hybrid heat spreader formation by direct growth onto low conductive substrate.

FIG. 6A-6G Hybrid heat spreader formation by transferring to secondary substrate;

FIGS. 7A-7E illustrates a manufacturing process;

FIGS. 8A-8C illustrate an example of a mode of use of the heterogeneous heat spreader embedded in substrate wafer;

FIGS. 9A-9C illustrate an example of a representation of recesses fabricated within substrate wafer according to thermal management pattern;

FIG. 10 illustrates an example of a placement on whole wafer or on wafer level heterogeneous heat spreader with repeated multi-die pattern;

FIGS. 11A-11D illustrate an example of embedding of diamond heat spreaders in the back side of a semiconductor wafer;

FIGS. 12A-12C illustrate an embedding of diamond heat spreaders in the back side of a semiconductor wafer;

FIGS. 13A and 13B illustrate an example of a cross section of the active die after dicing with embedded hybrid diamond heat spreader;

### DETAILED DESCRIPTION

There is provided a solution that involves hybrid diamond heat spreaders, where high thermally conductive diamond layer is adjusted to relatively low-cost substrate, like graphite, graphene, Si, SiC, Cu or others. Since the diamond layer is placed close to the heat source, it serves to reduce the heat flux, the second layer of lower cost material then provides additional mechanical strength and thickness. Also, the combined hybrid heat spreader has a higher effective CTE due to the balance between the expansion of the diamond layer and the second material.

What is achieved then is a heat spreader, which reduces the temperature similar to that of a pure diamond, but has less diamond content and also a tunable, higher CTE closer to that of the device hosting material attached to it, such that the devices are better protected from temperature induced effects of mechanical stress.

In general, the innovation described above of replacing the high heat conductivity diamond with a hybrid heat spreader composed of at least another material also applies to other high heat conductivity material other than diamonds. These multilayer heat spreaders will also better match the devices to be cooled (such as Si, GaN, SiC and alike) because part of the stress will be suppressed by the other material.

There may be provided a semiconductor unit that may include a hot areas generating portion that generates hot areas during operation; and a hybrid diamond heat spreaders (HDHSs) that are configured to dissipate at least part of the heat generated in the hot areas. A HDHS (one of the HDHSs, each one of the HDHSs or one of only a part of the HDHSs) may include a diamond layer of a first thickness, a first mechanical strength, a first thermal conductivity, and a first coefficient of thermal expansion (CTE); and a diamond layer support element of a second thickness, a second mechanical strength, and a second CTE.

According to one or more embodiments—at least one of the following is true:
a. The first thickness is lower than the second thickness.
b. The first mechanical strength is higher than the second mechanical strength.
c. The first thermal conductivity exceeds the second thermal conductivity.
d. The second CTE exceeds the first CTE.

According to one or more embodiments—at least one of the following is not true:
a. The first thickness is lower than the second thickness.
b. The first mechanical strength is higher than the second mechanical strength.
c. The first thermal conductivity exceeds the second thermal conductivity.
d. The second CTE exceeds the first CTE.

In order to dissipate the heat from the hot areas, the HDHSs are in thermal contact with the hot areas.

Some or all of the HDHSs may include the diamond layer and the diamond layer support element.

The semiconductor unit may be a single wafer, multiple wafers, a single die or multiple dies.

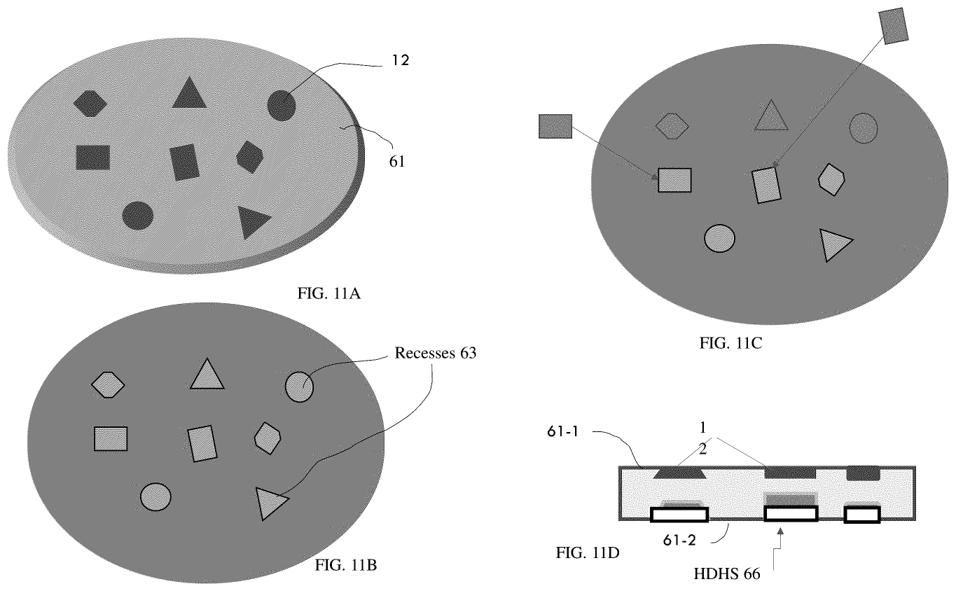

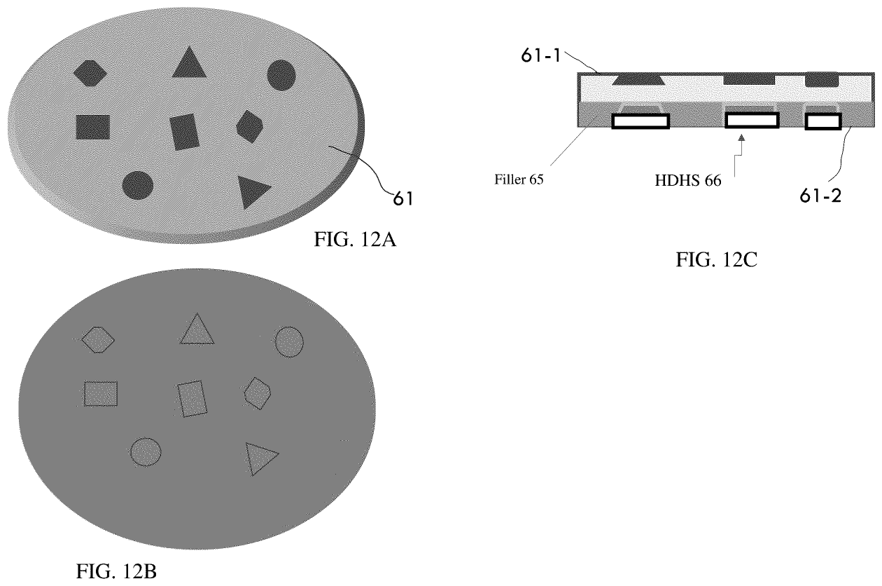

Assuming, for example that the semiconductor is a single wafer—the hot areas are formed at a first side (for example 61-1 of FIGS. 11D and 12C) of the semiconductor unit and the HDHSs are positioned within cavities formed in a second side (for example 61-2 of FIGS. 11D and 12C) of the semiconductor unit, the second side differs from the first side.

The HDHSs may be attached to the hot area generating portion and are at least partially surrounded by a filler. See, for example, FIG. 12C.

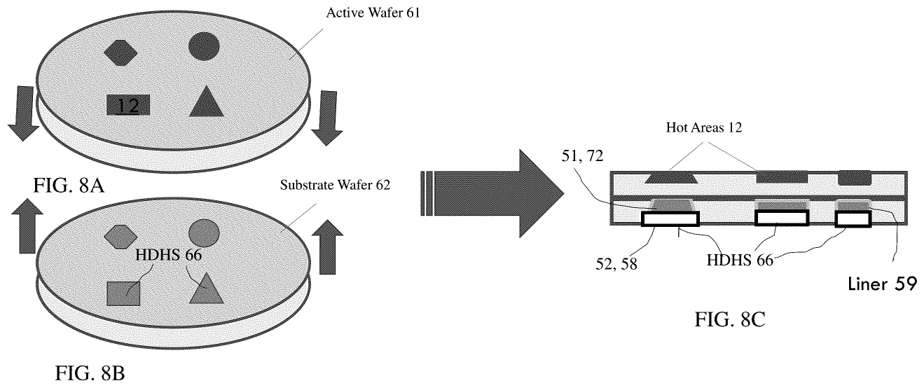

Alternatively, semiconductor unit may include a first wafer (for example an active wafer) and a second wafer (for example a substrate wafer). The hot area generating portion (for example active wafer 61 of FIG. 8B) belongs to the first wafer and the HDHSs are connected to the second wafer.

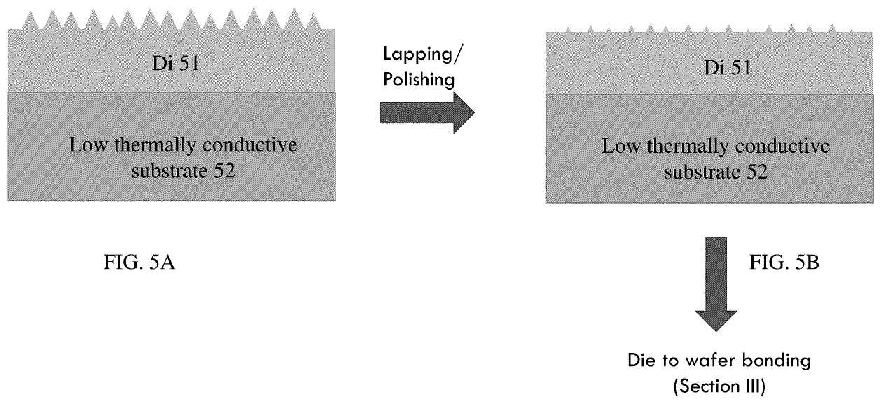

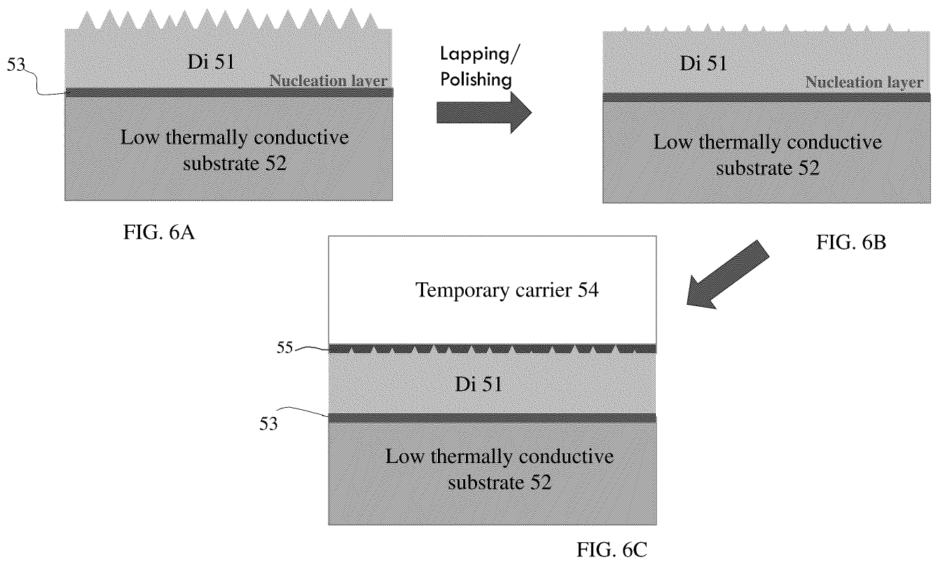

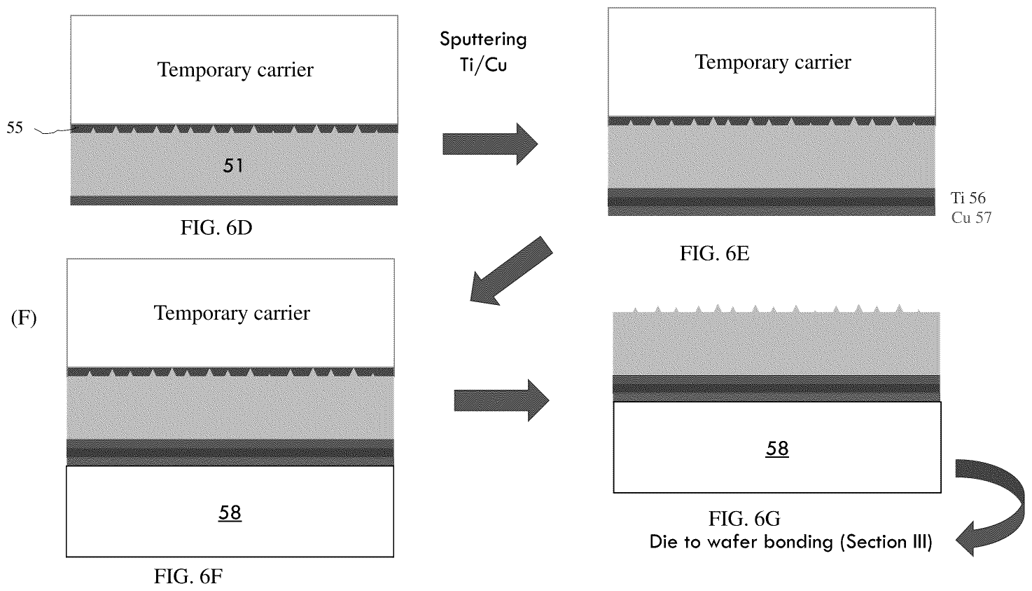

The HDHS may be manufactured by a manufacturing process that includes growing a diamond on top of the diamond layer support element. See, for example FIGS. 5A and 6A.

The manufacturing process may also include (i) polishing the diamond to provide the diamond layer (see FIG. 6B), (ii) gluing a temporary carrier to a top of the diamond layer (see, for example FIG. 6C), (iii) removing the diamond layer support element layer (see, for example FIG. 6D) (iv) forming one or more additional layers below the diamond layer (see, for example FIG. 6E and FIG. 6F); and (v) removing the temporary layer (see, for example FIG. 6G).

The one or more additional layers may include an interface layer and an additional substrate layer (see for example layer 58 of FIG. 6F). The one or more additional layers may include an adhesion layer.

The adhesion layer may be titanium layer or a chromium layer, or a copper containing layer. (See for example layers 56 and 57 of FIG. 6E). Other adhesion layer and/or other materials may be provided.

The HDHS may be manufactured by a manufacturing process that comprises obtaining diamond segments.

The HDHS may be manufactured by a manufacturing process that includes obtaining a diamond segment that is attached to the diamond layer support element.

The HDHS may be partially or fully surrounded by a liner-see for example liner 59 of FIG. 8C.

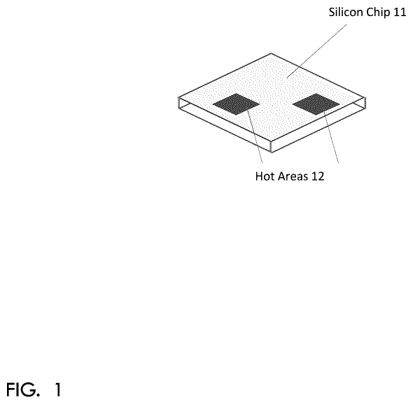

FIG. 1 illustrates an example of hot areas 12 on an active silicon chip 11.

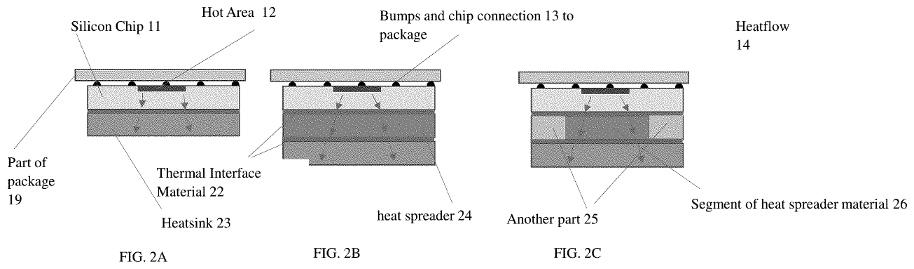

FIGS. 2A-2C illustrate examples of a cross section view of a silicon chip in package. The silicon chip is electronically connected to the package through bumps face down in “flip chip” geometry. Excess heat is removed from the back of the chip to the cooling system.

In FIG. 2A the silicon chip 11 is connected via a thermal interface material 22 to heatsink 23 which also functions as a heat spreader. The silicon chip 11 is also connected to package 19 via bumps and chip connections 13 to package.

In FIG. 2B a heat spreader 24 that is positioned between the silicon chip 11 and the heatsink 23, whereas there is a thermal interface material on each side of the heat spreader 24. The heat spreader cover the entire silicon chip.

The heatsink 23 may be connected to cooling fins or a water-cooling system (not shown) directly or through mechanism such as a heat pipe or vapor chamber (not shown). The thermal interface material 22 may be an organic (thermal grease) or metallic layer (such as Indium) or dielectric (in the case of direct wafer bonding) with thicknesses ranging from 0.01 to 100 microns. It is used in electronic packaging systems to ensure good thermal contact between materials or can be used at wafer bonding level to physical bond between wafers.

FIG. 2C demonstrates the concept of a heterogeneous heat spreader where a high thermal conductivity material 26 (such as a diamond) is embedded in the heat spreader only in regions under the hot areas where the thermal flux is high, thus achieving at lower bill of material while maintaining a similar reduced junction temperature for the hot area. The high thermal conductivity material 26 may be surrounded by another part 25 that is less expensive and of lower thermal conductivity in relation to the high thermal conductivity material 26.

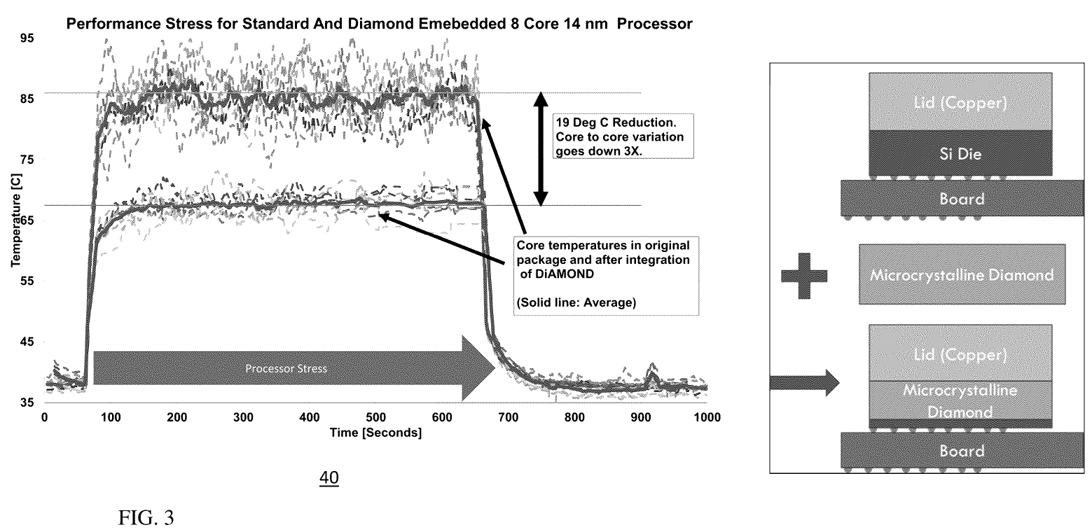

FIG. 3 illustrates an example of an impact (graph 40) for high thermal conductivity heat spreader (in this case microcrystalline diamond) on hot area temperature. The integration of the high thermal conductivity heat spreader reduces the hot area temperature in all eight cores by an average of nineteen degrees and reduces the variance of hot area temperature by a factor of 3. (presented as Performance Enhancement of Integrated Circuits and Power Devices via Embedded Diamond Heat Management proceeding of 2021 IEEE International Conference on Microwaves, Antennas, Communications and Electronic Systems (COMCAS) IEEExplore library.)

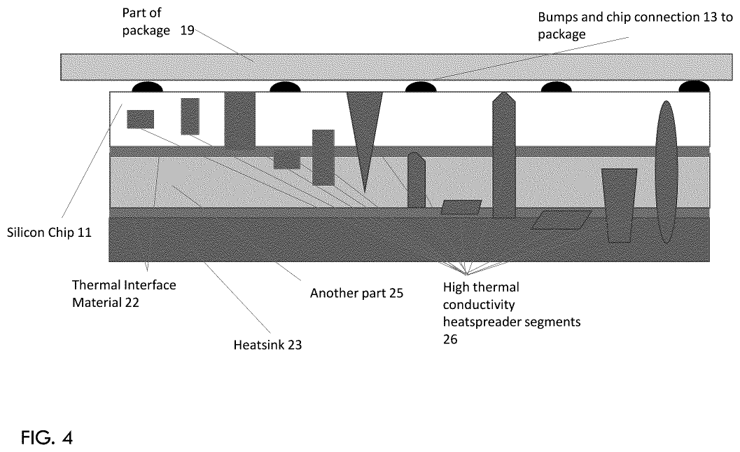

FIG. 4 illustrates an example of implementations of the heterogeneous heat spreader with embedded high thermal conductivity material 26 located at different parts of the device. FIG. 4 illustrates (from top to bottom): part of package 19, bumps and chip connections 13, silicon chip 11, a thermal interface material 22, a heat spreading layer that includes another part 25, another thermal interface material, and heatsink 23. Multiple segments of heterogeneous heat spreader with embedded high thermal conductivity material 26 are located in different locations. The device may include one or any combination or sub-combinations of the multiple segments.

### II. Hybrid Heat Spreader Preparation

Chemical vapor deposition (CVD) can be used to produce a synthetic diamond by creating the circumstances necessary for carbon atoms in a gas to settle on a substrate in crystalline form. CVD production of diamonds has received a great deal of attention in the materials sciences because it allows many new applications of diamonds that had previously been considered too difficult to make economical. CVD diamond growth typically occurs under low pressure and involves feeding varying amounts of gases into a chamber, energizing them and providing conditions for diamond growth on the substrate. The gases always include a carbon source, and typically include hydrogen as well, though the amounts used vary greatly depending on the type of diamond being grown.

FIG. 5A illustrates a deposition of CVD diamond layer 51 on low thermally conductive substrate 52.

FIG. 5B illustrates a Lapping/polishing of the growth side (the CVD diamond layer 51) to desired roughness—to provide a polished CVD diamond layer 51.

The low thermally conductive substrate (“substrate”) can be made of materials such as Si, SiC, Graphite etc.

Substrates of the desired thickness can be used and diamond film can be deposited on the top.

Substrate lateral dimensions can be significantly large than HS area (e.g., wafer) and desired lateral size can be achieved by dicing following deposition.

In other embodiments, substrate can be diced prior to deposition and CVD process may be done on multi-substrate level simultaneously. A thickness of a diamond layer (such as a CVD diamond layer) can be significantly lower than commonly used free standing heterogeneous diamond heat spreaders, which is more cost effective and yet have high thermal conductivity. Following multi-substrates lapping/polishing procedure these heat spreaders can be integrated in the device wafer, as described in Section III.

FIGS. 6A-6G illustrate hybrid heat spreader formation by transferring to secondary substrate.

FIG. 6A shows direct deposition of CVD diamond layer 51 on a low thermally conductive substrate 52) and a nucleation layer 53 formed at the interface between the CVD diamond layer 51 and the low thermally conductive substrate 52. It should be noted that the nucleation layer 53 may be removed.

This is followed by lapping/polishing of the growth side, which is illustrated on FIG. 6B.

The process continues by bonding a temporary carrier 54 (bonding layer 55) to polished side of the CVD diamond layer 51, as shown in FIG. 6C.

The process continues by grinding/elimination of the low thermally conductive substrate 52, shown in FIG. 6D.

In some embodiments, adhesion/thermal interface layer (or layers) can be deposited on the bottom of the polished side, as illustrated in FIG. 6E-illustrating a Titanium layer 56 and a copper layer 57 (other layers made of other materials can be formed).

The process continues by bonding of a secondary substrate 58 to the polished side, as illustrated in FIG. 6F. The secondary substrates can be made of materials such as copper, SiC, Graphite, Graphene etc. For example, in case of a Copper secondary substrate, it can be thermally bonded with Cu foil (thermocompression), electroplated or adhesive bonded or any other method of bonding.

Following temporary carrier 54 debonding (FIG. 6G) hybrid seeds can be integrated in the device wafer, as described in Section III.

In other embodiments, diamond can be used from any other bulk source, like high pressure high temperature, natural diamond etc.

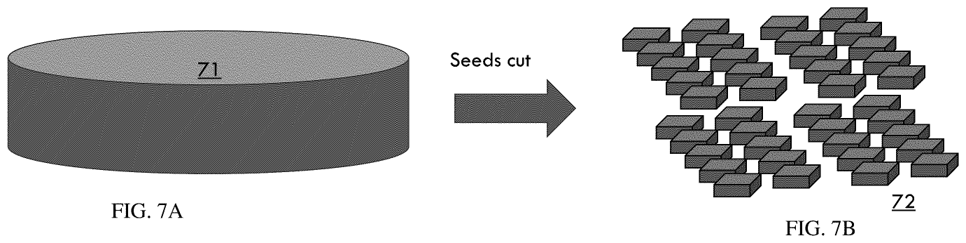

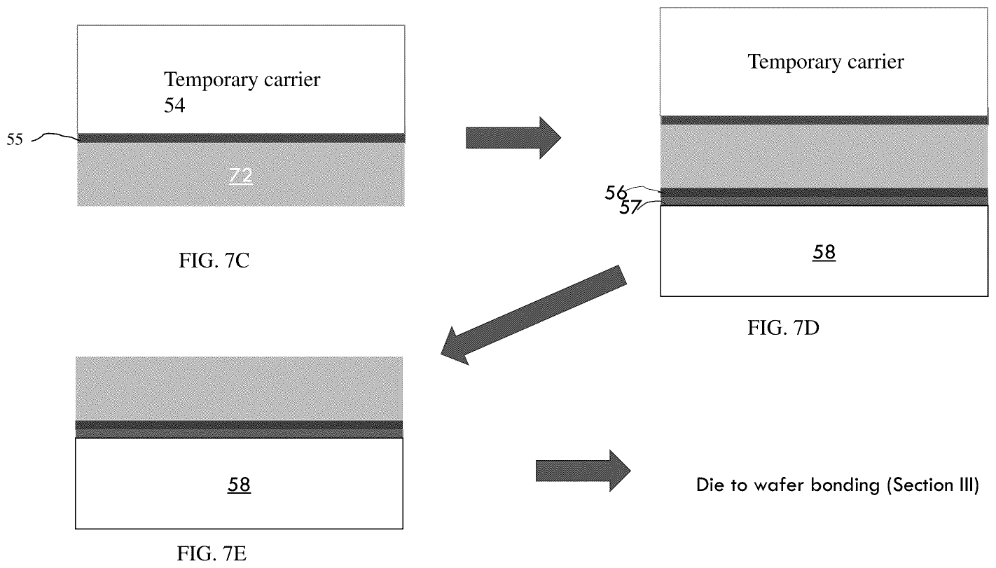

FIGS. 7A-7E illustrate this scenario.

FIG. 7A shows a large diamond bulk 71 from any source. It can have any geometrical shape, not just circle, as illustrates FIG. 7A. This bulk material may be cut to smaller seeds 72 of desired 3D dimensions, as illustrated in FIG. 7B.

It is worth to emphasize that seed's shape isn't limited to sheets (as shown in FIG. 7B) but any 3D shape can be formed from large scale bulk ingots.

Lapping/polishing procedures can be applied to these seeds, as well as cleaning procedures (wet clean or plasma clean), not shown in FIGS. 7A-7B.

The process continues by bonding a temporary carrier 54 (see bonding layer 55) to seed 72 using adhesive temporary bonding, fusion bonding, mechanical pressing etc., as illustrated in FIG. 7C.

In some embodiments, this step can be omitted.

The process continues by bonding of secondary substrate 58 to the back side of the seed 72, as illustrated in FIG. 7D. The secondary substrates can be made of materials such as copper, SiC, Graphite, Graphene etc. For example, in case of Copper secondary substrate, it can be thermally bonded with Cu foil (thermocompression), electroplated or adhesive bonded or any other method of bonding.

The process continues by temporary carrier debonding (FIG. 7E) and then hybrid seeds can be integrated in the device wafer, as described in Section III.

### III. Hybrid Heat Spreader Integration in Device Wafer

FIGS. 8A-8C illustrate an example of mode of use of the heterogeneous heat spreader embedded in substrate wafer 62.

FIG. 8A illustrates an example of an active wafer 61 with schematic hot areas 12 on the top before integration.

FIG. 8B illustrates an example of a heterogenous heat spreader formed by embedding HDHSs 66 in substrate wafer 62 or other material.

FIG. 8B also illustrates a HDHS that is partially or fully surrounded by a liner 59.

The liner may the HDHSs from being exposed to the wafer edge. The liner may ensure adhesion, good thermal contact between embedded HDHSs and the embedding subtract wafer

FIG. 8C illustrates an example of a cross section view of active wafer bonded to the heterogeneous heat spreader. The active wafer and the Heterogeneous heat spreader are aligned such that the HDHSs 66 are directly beneath the hot areas. An HDHS may include a diamond layer 51 or a seed 72—and may also include a diamond layer support element such as 52 or 58.

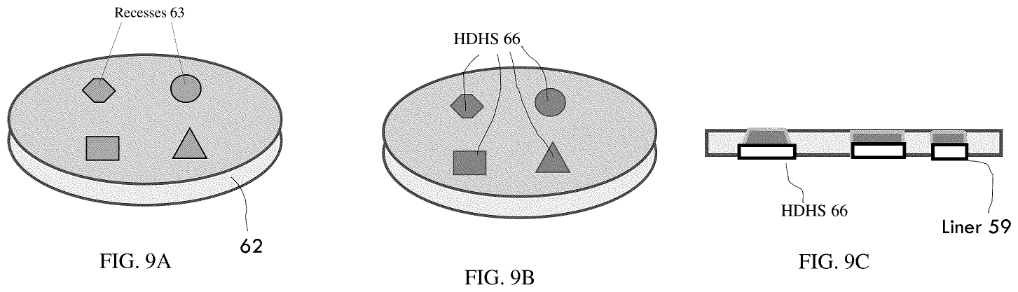

FIG. 9A illustrates an example of recesses 63 fabricated within substrate wafer 62.

FIG. 9B illustrates an example of HDHSs 66 embedded in each recess in substrate wafer.

FIG. 9C illustrates an example of a cross section view. It shows HDASs 66 in an substrate wafer. The HDHS may be partially or fully surrounded by liner 59.

These recesses can be fabricated in the substrate wafer by any technique, such as RIE, wet etch, laser ablation, thermochemical etching, micro-CNC drilling, mechanical grinding, etc. The depth of recesses can vary from several nm to hundreds of microns, while lateral dimensions can vary from tens of microns to several millimeters. The roughness of recess wells and bottom can be in sub-nanometer to hundreds of micron range.

Each recess 63 is filled by specially prepared HDHSs 66, as shown in FIG. 9B.

Filling may mean any proximity connection between two materials, such as temporary bonding, permanent bonding, adhesive bonding, mechanical pressing etc. The bonding between the HDHSs and the substrate wafer may be done by any method that can ensure good enough adhesion. It can be done by direct or indirect bonding. It may involve intermediate layers for bonding, adhering, welding, soldering, sintering, fusion or any other mechanism of attaching to surfaces to each other. It may involve the application of pressure, heat, gas flow, radiation, or any other additional process parameter that may be required for bonding. It may involve additional post-bonding processes such as annealing or curing that may enhance the bond quality, strength, thermal conductivity, and other properties.

The HDHS production process may involve any required step of surface preparation prior to the positioning of the heat spreaders at the recesses. For example, it may involve cleaning, polishing, activation, heating, drying, coating by primer, adhesion layer, metallization, and any additional process required for bonding or for improving the thermal conductivity across the bonding interface. This is applicable to both parts to be bonded, the substrate wafer and the heat spreaders.

In one implementation, to allow the adhesion and relief of stress due to differences between thermal expansion coefficients, a liner 59 (FIG. 9C) is included between the embedded HDHSs within the embedding substrate wafer. The liner can be composed from any of the following materials but not only limited to, SiO₂ or Graphite, Indium silver or polymeric glue.

The positioning of the heat spreaders into the recessed areas at the semiconductor wafer may be done by any method that is capable of die to wafer positioning. It can be done manually or automatically, it can be done for example by pick and place tool, by die attach tool, or any other capable means. It can be done by positioning the diamond heat spreaders one by one at the recesses, or by pre-distribution of the diamond heat spreaders on a carrier, and collective transfer of multiple number of heat spreaders from the carrier to the semiconductor wafer recesses. The final result is demonstrated by FIG. 9B and cross section is shown in FIG. 9C where all the recesses filled by heat spreaders.

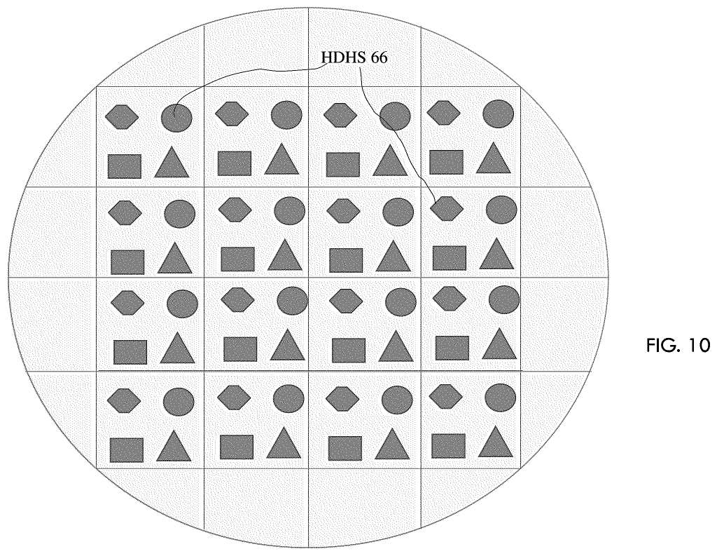

FIG. 10 illustrates an example of a placement of HDHSs 66 on whole wafer or on wafer level heterogeneous heat spreader with repeated multi-die pattern. This scenario holds for integration of heterogeneous HDHSs within substrate wafer as well as with active device wafer.

FIGS. 11A-11D illustrate an example hot areas 12 formed on a first side 61-1 of active wafer 61, recesses 63 for receiving HDSSs 66 formed on a second side 61-2 of the active wafer 61. FIG. 11A illustrates an example of a front side of active semiconductor wafer with schematic hot areas on the top before integration. FIG. 11B illustrates an example of a back side of active semiconductor wafer with recesses created beneath hot area before integration. FIG. 11C illustrates an example of an integrated backside of active semiconductor wafer demonstrates the positioning of the HDHSs of different size and shapes into the recessed areas at the active device wafer backside. FIG. 11D illustrates an example of a cross section view of integrated active device wafer with embedded heat spreader segments. Liner ensures adhesion, good thermal contact between embedded HDHSs and the embedding subtract wafer.

FIGS. 12A-12C illustrate embedding of HDHSs 66 in the back side 61-1 of an active wafer 61. FIG. 12A illustrates an example of a front side 61-1 of the active wafer with schematic hot areas 12 on the top before integration. FIG. 12B illustrates an example of a back side 61-2 of active wafer thinned on the wafer level to required (optimized) thickness to allow closest proximity of the heat spreader to hot area. HDHSs are bonded to the back side of the thinned device wafer. FIG. 12C illustrates an example of a cross section view of integrated active device wafer with embedded heat spreader segments. Liner (not shown) may at least partially surround the HDHSs and may ensures adhesion, good thermal contact between embedded HDHSs and the embedding subtract wafer. Filer 65 is used to bring wafer backside to uniform thickness.

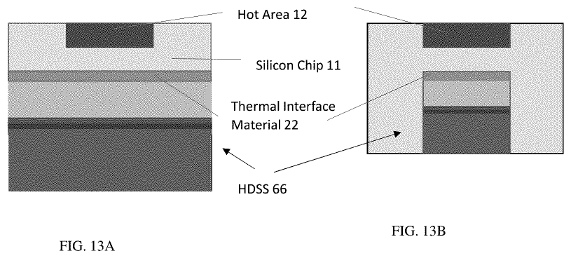

FIGS. 13A and 13B illustrate examples of cross sections of the active die after dicing with embedded diamond heat spreader. In FIG. 13A the HDHS is at the die size. In FIG. 13B the HDHS is smaller than the die and is selectively positioned at a recess, at the vicinity of the hot operation area. FIGS. 13A and 13B illustrate hot area 12, silicon chip 12, thermal interface and HDSS 66.

Any reference to the term “comprising” or “having” should be applied mutatis mutandis interpreted also as referring to “consisting” of “essentially consisting of”. For example—a method that comprises certain steps can include additional steps, can be limited to the certain steps or may include additional steps that do not materially affect the basic and novel characteristics of the method-respectively.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A semiconductor unit that comprises:
a hot areas generating portion that generates hot areas during operation; and
hybrid diamond heat spreaders (HDHSs) that are configured to dissipate at least part of the heat generated in the hot areas;
wherein a HDHS of the HDHSs comprises at least two layers that include:
a diamond layer of a first thickness, a first mechanical strength, a first thermal conductivity, and a first coefficient of thermal expansion (CTE); and
a diamond layer support element of a second thickness, a second mechanical strength, and a second CTE.

2. The semiconductor unit according to claim 1 wherein at least one of the following is true:
(a) the first thickness is lower than the second thickness;
(b) the first mechanical strength is higher than the second mechanical strength;
(c) the first thermal conductivity exceeds the second thermal conductivity; or
(d) the second CTE exceeds the first CTE.

3. The semiconductor unit according to claim 2 wherein the first thickness is lower than the second thickness, the first mechanical strength is higher than the second mechanical strength, the first thermal conductivity exceeds the second thermal conductivity; and the second CTE exceeds the first CTE.

4. The semiconductor unit according to claim 1, wherein the semiconductor unit is a single wafer.

5. The semiconductor unit according to claim 4, wherein the hot areas are formed at a first side of the semiconductor unit and the HDHSs are positioned within cavities formed in a second side of the semiconductor unit, the second side differs from the first side.

6. The semiconductor unit according to claim 4, wherein the HDHSs are attached to the hot area generating portion and are at least partially surrounded by a filler.

7. The semiconductor unit according to claim 1, wherein the semiconductor unit comprises a first wafer and a second wafer, wherein the hot area generating portion belongs to the first wafer and the HDHSs are connected to the second wafer.

8. The semiconductor unit according to claim 1, wherein the HDHS is manufactured by a manufacturing process that comprises growing a diamond on top of the diamond layer support element.

9. The semiconductor unit according to claim 1, wherein the manufacturing process further comprises:
polishing the diamond to provide the diamond layer;
gluing a temporary carrier to a top of the diamond layer;
removing the diamond layer support element;
forming one or more additional layers below the diamond layer; and
removing the temporary layer.

10. The semiconductor unit according to claim 9, wherein the one or more additional layers comprise an interface layer and an additional substrate layer.

11. The semiconductor unit according to claim 9, wherein the one or more additional layers comprise an adhesion layer.

12. The semiconductor unit according to claim 11, wherein the adhesion layer is a titanium layer or a chromium layer, or a copper containing layer.

13. The semiconductor unit according to claim 1, wherein the HDHS is manufactured by a manufacturing process that comprises obtaining diamond segments.

14. The semiconductor unit according to claim 1, wherein the HDHS is manufactured by a manufacturing process that comprises obtaining a diamond segment that is attached to the diamond layer support element.

15. The semiconductor unit according to claim 1, wherein the semiconductor unit is a single die.

16. The semiconductor unit according to claim 1, wherein the HDHSs are in thermal communication with the hot areas generating portion and are in mechanical communication with the hot areas generating portion.

17. A method for manufacturing a silicon unit, the method comprises
obtaining a hot areas generating portion that generates hot areas during operation;
obtaining hybrid diamond heat spreaders (HDHSs); and
establishing a thermal communication between the hot areas generating portion and the HDHSs; wherein once established, the HDHSs are configured to dissipate at least part of the heat generated in the hot areas; wherein a HDHS of the HDHSs comprises: (i) a diamond layer of a first thickness, a first mechanical strength, a first thermal conductivity, and a first coefficient of thermal expansion (CTE); and (ii) a diamond layer support element of a second thickness, a second mechanical strength, and a second CTE; wherein the first thickness is lower than the second thickness, the first mechanical strength is higher than the second mechanical strength, the first thermal conductivity exceeds the second thermal conductivity and the second CTE exceeds the first CTE.

18. The method according to claim 17 wherein at least one of the following is true:
(a) the first thickness is lower than the second thickness;
(b) the first mechanical strength is higher than the second mechanical strength;
(c) the first thermal conductivity exceeds the second thermal conductivity; or
(d) the second CTE exceeds the first CTE.

19. The method according to claim 18 wherein the first thickness is lower than the second thickness, the first mechanical strength is higher than the second mechanical strength, the first thermal conductivity exceeds the second thermal conductivity; and the second CTE exceeds the first CTE.
